(19) United States
(12) Patent Application Publication
(10) Pub. No.: US 2025/0391652 A1
(43) Pub. Date: Dec. 25, 2025

(54) SUBSTRATE PROCESSING METHOD, SUBSTRATE PROCESSING DEVICE, AND STORAGE MEDIUM

(71) Applicant: Tokyo Electron Limited, Minato-ku, Tokyo (JP)

(72) Inventors: Hiroyuki SUZUKI, Koshi-shi, Kumamoto (JP); Yumi SASAKI, Minato-ku, Tokyo (JP)

(21) Appl. No.: 18/879,383

(22) PCT Filed: Jun. 27, 2023
(86) PCT No.: PCT/JP2023/023820

§ 371 Date: Dec. 27, 2024

(30) Foreign Application Priority Data
Jul. 4, 2022 (JP) 2022-107964

(51) Int. Cl. H01L 21/02; H01L 21/67; H01L 21/687

(52) U.S. Cl. CPC H01L 21/02057; H01L 21/67034; H01L 21/67051; H01L 21/68764

(57) ABSTRACT

A substrate processing method includes: forming a liquid film of a protective liquid, which covers a front surface of a substrate, by supplying the protective liquid, which protects a front surface pattern of the substrate, to the front surface where a liquid processing using a processing liquid has been performed; loading the substrate with the liquid film formed thereon into a processing container; supplying a pressurized processing fluid into the processing container, replacing the processing liquid on the substrate with the pressurized processing fluid supplied while maintaining an internal pressure of the processing container at a level where the processing fluid remains in a supercritical state, discharging the processing fluid from the processing container, and drying the substrate; and cleaning a rear surface of the substrate by supplying a cleaning liquid to the rear surface, wherein the cleaning is performed at least while the forming the liquid film is performed.

### TECHNICAL FIELD

The present disclosure relates to a substrate processing method, a substrate processing apparatus, and a storage medium.

### BACKGROUND

In a process of manufacturing semiconductor devices in which a stacked structure of integrated circuits is formed on a surface of a substrate such as a semiconductor wafer (hereinafter referred to as “wafer”), a liquid processing such as chemical cleaning or wet etching is performed. In recent years, when removing a liquid and others adhered to the surface of the wafer during such a liquid processing, a drying method using a processing fluid in a supercritical state has been used (see, for example, Patent Document 1).

### PRIOR ART DOCUMENTS

### Patent Documents

Patent Document 1: Japanese Patent Laid-Open Publication No. 2014-101241.

The present disclosure provides a technique capable of preventing adhesion of particles onto a substrate.

### SUMMARY

According to one embodiment of the present disclosure, a substrate processing method includes: forming a liquid film of a protective liquid, which covers a front surface of a substrate, by supplying the protective liquid, which protects a front surface pattern of the substrate, to the front surface of the substrate on which a liquid processing using a processing liquid has been performed; loading the substrate, after the forming the liquid film, into a processing container in a state where the liquid film of the protective liquid is formed; supplying a pressurized processing fluid, after the loading the substrate, into the processing container, replacing the processing liquid on the substrate with the pressurized processing fluid supplied into the processing container while maintaining an internal pressure of the processing container at a level where the processing fluid remains in a supercritical state, discharging the processing fluid from the processing container, and drying the substrate; and cleaning a rear surface of the substrate by supplying a cleaning liquid, which cleans the rear surface of the substrate, to the rear surface of the substrate, wherein the cleaning the rear surface is performed at least while the forming the liquid film is performed.

According to the present disclosure, it is possible to prevent adhesion of particles onto a substrate.

### BRIEF DESCRIPTION OF DRAWINGS

FIG. 1 is a schematic transverse cross-sectional view of a substrate processing system according to one embodiment of a substrate processing apparatus.

FIG. 2 is a schematic longitudinal cross-sectional view of a liquid processing unit included in the substrate processing system.

FIG. 3 is a schematic longitudinal cross-sectional view of a supercritical drying unit included in the substrate processing system.

FIGS. 4A to 4L are schematic diagrams illustrating a series of steps executed in the liquid processing unit.

FIG. 5 is a schematic diagram illustrating a state where a processing liquid supplied to a front surface of a substrate flows around to a rear surface of the substrate.

### DETAILED DESCRIPTION

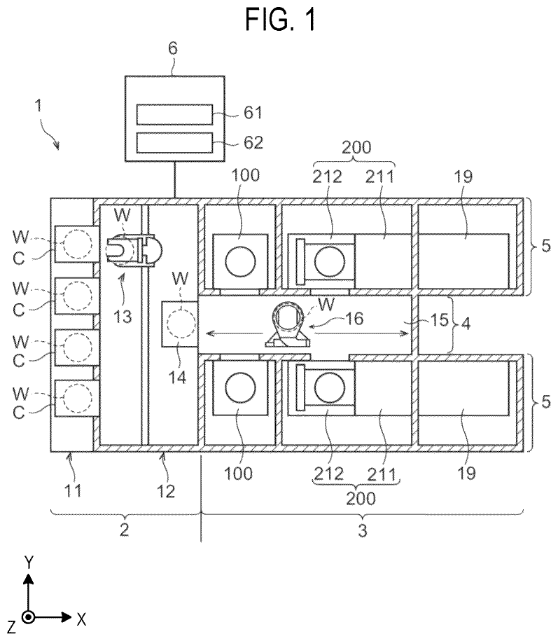

Hereinafter, a configuration of a substrate processing system 1 according to one embodiment of a substrate processing apparatus is briefly described with reference to FIG. 1. For simplicity of description, an XYZ Cartesian coordinate system (see the bottom left of FIG. 1) is set and referenced as appropriate.

### Overall Configuration of Substrate Processing System

As illustrated in FIG. 1, the substrate processing system 1 includes a loading/unloading station 2 and a processing station 3.

The loading/unloading station 2 includes a load port 11 and a transfer block 12. A plurality of carriers C are placed on the load port 11. Each carrier C accommodates a plurality of substrates W (e.g., semiconductor wafers) in a horizontal posture and at intervals in a vertical direction.

A transfer device 13 and a delivery unit 14 are provided inside the transfer block 12. The delivery unit 14 includes an unprocessed substrate stage for temporarily placing one or more unprocessed substrates W (substrates W before being processed in the processing station 3), and a completely processed substrate stage for temporarily placing one or more completely processed substrates W (substrates W that have been processed in the processing station 3). The transfer device 13 may transfer the substrates W between any carrier C placed on the load port 11 and the delivery unit 14.

The processing station 3 includes a transfer block 4 and a pair of processing blocks 5 provided on both sides of the transfer block 4 in a Y direction. Each processing block 5 is provided with a liquid processing unit 100, a supercritical drying unit 200, and a processing fluid supply cabinet 19. In the present embodiment, the liquid processing unit 100 and the supercritical drying unit 200 are single-wafer type processing units. Processing fluids required for processing are supplied from the processing fluid supply cabinet 19 to the liquid processing unit 100 and the supercritical drying unit 200.

The transfer block 4 includes a transfer area 15 and a transfer device 16 located inside the transfer area 15. The transfer device 16 may transfer the substrates W among the delivery unit 14, any liquid processing unit 100, and any supercritical drying unit 200.

Each processing block 5 may have a multilayer (e.g., three-layer) structure. In this case, each layer is provided with one liquid processing unit 100, one supercritical drying unit 200, and one processing fluid supply cabinet 19. In this case, one transfer device 16 may be capable of accessing the liquid processing units 100 and the supercritical drying units 200 of all layers.

The substrate processing system 1 includes a control device 6. The control device 6 is, for example, a computer, and includes an operation processor 61 and a storage 62. The operation processor 61 includes a microcomputer having a Central Processing Unit (CPU), a Read Only Memory (ROM), a Random Access Memory (RAM), input/output ports, and others, or includes various circuits. The CPU of such microcomputer reads and executes programs stored in the ROM, thereby executing the control of the transfer devices 13 and 16, liquid processing unit 100, supercritical drying unit 200, processing fluid supply cabinet 19, and others. In addition, these programs may be recorded on a computer-readable storage medium (non-transitory storage medium), and installed from the storage medium to the storage 62 of the control device 6. Examples of the computer-readable storage medium include hard disks (HD), flexible disks (FD), compact disks (CD), magneto-optical disks (MO), memory cards, and others. The storage 62 is realized, for example, by semiconductor memory elements such as a RAM and a flash memory, or by storage devices such as hard disks and optical disks.

Next, a transfer flow of the substrate W in the substrate processing system 1 described above is briefly described.

An external transfer robot (not illustrated) places the carrier C accommodating the unprocessed substrates W on the load port 11. The transfer device 13 takes out one substrate W from the carrier C and loads it into the delivery unit 14. The transfer device 16 takes out the substrate W from the delivery unit 14 and loads it into the liquid processing unit 100.

A liquid processing composed of a plurality of steps is performed inside the liquid processing unit 100. Details of the liquid processing are described later, but in the final step, an IPA liquid film (also referred to as “IPA paddle”) with a predetermined film thickness is formed on a front surface of the substrate W.

Next, the substrate W with the IPA paddle formed on the front surface thereof is taken out from the liquid processing unit 100 by the transfer device 16 and is loaded into the supercritical drying unit 200. In the supercritical drying unit 200, the substrate W is dried by using a supercritical drying technique, in a sequence to be described later. The supercritical drying technique may be advantageously used for drying substrates with fine and high-aspect-ratio patterns formed thereon since surface tension, which may cause pattern collapse, does not act on the patterns. Afterwards, the transfer device 16 takes out the dried substrate W from the supercritical drying unit 200 and loads it into the delivery unit 14. The transfer device 13 takes out the substrate W from the delivery unit 14 and accommodates it in the original carrier C placed on the load port 11. In this way, a series of processing for one substrate is terminated.

### Liquid Processing Unit

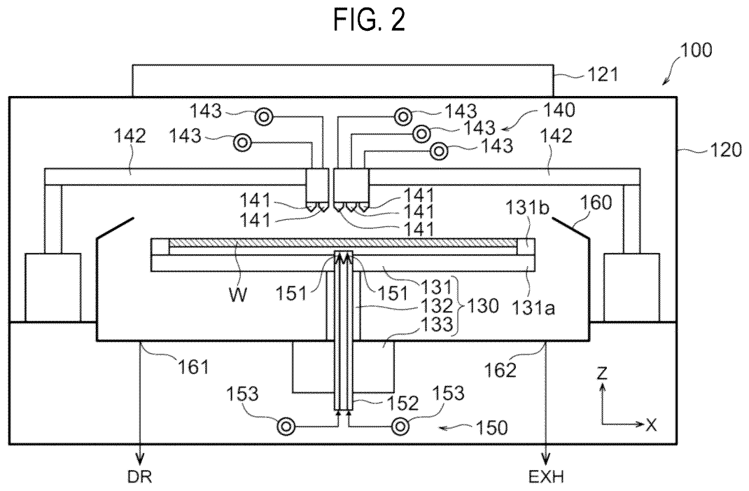

Next, a configuration of the liquid processing unit 100 is described with reference to FIG. 2.

The liquid processing unit 100 includes a chamber 120, a substrate holding rotator 130, a first processing fluid supplier 140, a second processing fluid supplier 150, and a collection cup 160.

The chamber 120 accommodates the substrate holding rotator 130 and the collection cup 160. A Fan Filter Unit (FFU) 121 is provided on a ceiling of the chamber 120. The FFU 121 forms a downflow inside the chamber 20.

The substrate holding rotator 130 includes a substrate holder 131, a support column (rotating shaft) 132, and a rotation drive 133. The substrate holder 131 is configured as a mechanical chuck including a disc-shaped base 131a and a plurality of gripping hooks 131b provided on an outer peripheral edge of the base 131a at intervals in a circumferential direction. The substrate holder 131 horizontally holds the substrate W by using the gripping hooks 131b. When the gripping hooks 131b are gripping the substrate, a gap is formed between an upper surface of the base 131a and a lower surface of the substrate W.

The support column 132 is a hollow member extending in a vertical direction. An upper end of the support column 132 is connected to the base 131a. For example, the rotation drive 133, constituted by an electric motor, rotates the support column 132, thereby allowing the substrate holder 131 and the substrate W held thereby to rotate around a vertical axis.

The collection cup 160 is disposed to surround the substrate holder 131. The collection cup 160 collects the processing liquid scattered from the substrate W, which is held by and rotated with the substrate holder 131. A drain port 161 is formed at a bottom of the collection cup 160. The processing liquid collected by the collection cup 160 is discharged to an outside of the liquid processing unit 100 from the drain port 161. An exhaust port 162 is formed at the bottom of the collection cup 160. An internal space of the collection cup 160 is suctioned through the exhaust port 162. A gas supplied from the FFU 121 is drawn into an interior of the collection cup 160 and is then discharged to the outside of the liquid processing unit 100 through the exhaust port 162.

The first processing fluid supplier 140 supplies various processing fluids (such as liquids, gases, and gas-liquid mixed fluids) to an upper surface of the substrate W (front surface of the substrate W where devices are formed) held by the substrate holder 131. The first processing fluid supplier 140 includes one or more front surface nozzles 141 that eject the processing fluids toward the front surface of the substrate W. The number of front surface nozzles 141 is determined by the number necessary to perform the processing in the liquid processing unit 100. FIG. 2 illustrates five front surface nozzles 141, but the number is not limited thereto.

The first processing fluid supplier 140 includes one or more (two in the illustrated example) nozzle arms 142. Each nozzle arm 142 carries at least one of the plurality of front surface nozzles 141. Each nozzle arm 142 may move the carried front surface nozzle 141 between a position (processing position) roughly above a rotation center of the substrate W and a retracted position (home position) outside a top opening of the collection cup 160.

A processing fluid is supplied to each of the front surface nozzles 141 from a corresponding processing fluid supply mechanism 143. The processing fluid supply mechanism 143 may be composed of a processing fluid source such as a tank, cylinder, or factory utility, a supply pipe that supplies the processing fluid (processing liquid or processing gas) from the processing fluid source to the front surface nozzle 141, and a flow-rate adjuster such as an opening/closing valve and a flow-rate control valve provided at the supply pipe. To discharge the processing fluid (particularly, processing liquid) that remains in the front surface nozzle 141 and nearby supply pipe, a drain pipe may be connected to the supply pipe. Such processing fluid supply mechanism 143 is widely known in the technical field of semiconductor manufacturing apparatuses, and therefore, structure illustrations and detailed descriptions are omitted. A liquid sump (not illustrated) is provided to enable dummy dispensing when each front surface nozzle 141 is at the retracted position.

The second processing fluid supplier 150 supplies various processing fluids (such as processing liquids and processing gases) to the lower surface of the substrate W (rear surface of the substrate W where devices are typically not formed) held by the substrate holder 131. The second processing fluid supplier 150 includes one or more (two in the illustrated example) rear surface nozzles 151 that eject a processing fluid toward the lower surface of the substrate W. As schematically illustrated in FIG. 2, a processing liquid supply pipe 152 extends vertically in an interior of the hollow support column 132. Top openings of two flow paths extending vertically inside the processing liquid supply pipe 152 serve as the rear surface nozzles 151, respectively. The processing liquid supply pipe 152 is installed inside the support column 132 such that it may remain in a non-rotating state even when the substrate holder 131 and the support column 132 are rotating.

A processing fluid is supplied to each of the rear surface nozzles 151 from a corresponding processing fluid supply mechanism 153. The processing fluid supply mechanism 153 has the same configuration as the processing fluid supply mechanism 143 for the front surface nozzle 141 described above.

The second processing fluid supplier 150 is also configured to be capable of supplying a drying gas to a space below the substrate W (specifically, a space between the rear surface of the substrate W and the disc-shaped base 131a of the substrate holder 131). This configuration may be realized by providing a gas supply path (not illustrated), similar to the processing liquid supply path, inside the processing liquid supply pipe 152, or by utilizing, as a gas supply path, a gap between an outer peripheral surface of the processing liquid supply pipe 152 and inner peripheral surfaces of the support column 132 and the base 131a. The drying gas is preferably a gas with low humidity and low oxygen concentration, and particularly, may be a nitrogen (N₂) gas. Such a drying gas may also be supplied from the processing fluid supply mechanism 153.

In addition, it is known to provide a plurality of switchable flow paths in the interior of the collection cup 160 in addition to the drain port 161 corresponding to each flow path, thereby allowing different types of liquids (acids, alkalis, and organics) to be discharged through different paths. Further, it is also known to provide a switching mechanism in the exhaust port 162 to allow different types of liquids (acids, alkalis, and organics) to flow to different discharge locations. The configuration related to these functions is omitted from the drawings, for simplicity thereof.

### Supercritical Drying Unit

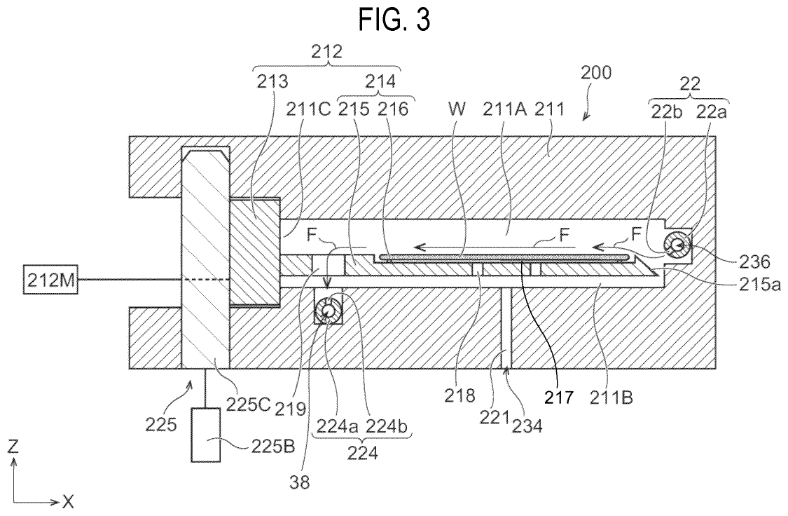

Next, the supercritical drying unit 200 is described with reference to FIG. 3. The supercritical drying unit 200 includes a processing container 211 and a substrate holding tray 212 (hereinafter simply referred to as “tray 212”) that holds the substrate W inside the processing container 211.

The tray 212 includes a lid 213 that covers an opening 211C provided at a sidewall of the processing container 211, and a horizontally extending substrate holder 214 integrally connected to the lid 213. The substrate holder 214 includes a plate 215 and a plurality of support pins 216 provided on an upper surface of the plate 215. The substrate W is placed in a horizontal posture on the support pins 216 with a front surface thereof (surface where devices or patterns are formed) facing upward. When the substrate W is placed on the support pins 216, a gap 217 is formed between the upper surface of the plate 215 and the lower surface (rear surface) of the substrate W.

The plate 215 includes a plurality of through-holes 218 formed therein to vertically penetrate the plate 215. The plurality of through-holes 218 serve to introduce a processing fluid supplied to a space below the plate 215 into a space above the plate 215. Some of the plurality of through-holes 218 also serve to allow for passage of lift pins (located directly below the tray 212 illustrated in FIG. 1 but hidden from view by the tray 212) that deliver the substrate W between the substrate holder 214 of the tray 212 (see FIG. 1) drawn out from the processing container 211 and the transfer device 16 (see FIG. 1).

The tray 212 may move horizontally (in a X direction) between a closed position (as illustrated in FIG. 3) and an open position (as illustrated in FIG. 1) by a tray moving mechanism 212M (schematically illustrated only in FIG. 1).

In the closed position of the tray 212, the substrate holder 214 is located in an internal space of the processing container 211, and the lid 213 closes the opening 211C at the sidewall of the processing container 211. In the open position of the tray 212, the substrate holder 214 protrudes out of the processing container 211 (see FIG. 1), allowing the substrate W to be delivered between the substrate holder 214 and a substrate transfer arm (not illustrated) via the aforementioned lift pins.

When the tray 212 is in the closed position, the plate 215 divides the internal space of the processing container 211 into an upper space 211A above the plate 215, where the substrate W is present during the processing, and a lower space 211B below the plate 215. However, the upper space 211A and the lower space 211B are not completely separated, and communicate with each other through, for example, the through-holes 218, an elongated hole 219, and a gap between a peripheral edge of the plate 215 and an inner wall surface of the processing container 211.

The processing container 211 is provided with a first ejector 221 and a second ejector 22. The first ejector 221 and the second ejector 22 eject a processing fluid (in this example, carbon dioxide (hereinafter referred to as “CO₂” for convenience)) supplied from a source (not illustrated) for a supercritical fluid (processing fluid in a supercritical state) into the internal space of the processing container 211.

The first ejector 221 is located below the plate 215 of the tray 212 in the closed position. The first ejector 221 ejects CO₂ (processing fluid) into the lower space 211B toward a lower surface of the plate 215 (in an upward direction).

The second ejector 22 is positioned in front of (at a forwardly advanced position in a positive X direction) of the substrate W placed on the substrate holder 214 of the tray 212 in the closed position. The second ejector 22 supplies CO₂ into the upper space 211A.

The second ejector 22 is configured with a rod-shaped nozzle body. Specifically, the second ejector 22 is formed by drilling a plurality of ejection holes 22b on a pipe 22a that extends in a width direction (Y direction) of the substrate W. The plurality of ejection holes 22b are arranged at equal intervals in the Y direction, for example. Each ejection hole 222b supplies CO₂ into the upper space 212A toward the opening 211C (approximately in a negative X direction).

The processing container 211 is further provided with a fluid discharger 224 that discharges the processing fluid from the internal space of the processing container 211. The fluid discharger 224 is configured as a header with approximately the same configuration as the second ejector 22. Specifically, the fluid discharger 224 is formed by drilling a plurality of discharge holes 224b on a horizontally extending pipe 224a. The plurality of discharge holes 224b are arranged at equal intervals in the Y direction, for example. Each discharge hole 224b is directed upward and is also directed toward the elongated hole 219 formed at the plate 215.

As illustrated by arrows F in FIG. 1, CO₂ flows through a region above the substrate W in the upper space 211A, and is then introduced into the lower space 211B through a communication path provided around the peripheral edge of the plate 215 (or the elongated hole 219 formed in the plate 215), followed by being discharged from the fluid discharger 224.

The processing unit 210 is provided with a locking mechanism 225, which includes a latch-shaped locking member 225C for securing the tray 212 in the closed position and a lift 225B for raising or lowering the locking member 225C between a locking position (position illustrated in FIG. 3) and a lowered unlocking position.

### Supercritical Drying

A processing performed using the supercritical drying unit 200 is briefly described below.

### Substrate Loading Step

In the liquid processing unit 100, the substrate W with the IPA paddle formed on the front surface thereof is taken out from the liquid processing unit 100 by the transfer device 16 inside the transfer area 15, and is then loaded into the supercritical drying unit 200. In the supercritical drying unit 200, the tray 212 is in the open position (position illustrated in FIG. 1), and the aforementioned lift pins (not illustrated) pass through through-holes (not illustrated) formed at the substrate holder 214 of the tray 212, with tips of the lift pins positioned above the substrate holder 214. The transfer device 16 places the substrate W on the lift pins, and the substrate W is then placed onto the tray 212 as the lift pins are lowered. Next, the tray 212 moves to the closed position, the substrate W is accommodated inside the processing container 211, and an interior of the processing container 211 is sealed. In this state, supercritical drying is performed.

### Pressure Increasing Step

First, a pressure increasing step is performed.

CO₂ (processing fluid) supplied from the supercritical processing fluid source is ejected from the first ejector 221 into the lower space 211B of the processing container 211. Since the interior of the processing container 211 is at atmospheric pressure immediately after the supply of CO₂ is initiated, the gaseous CO₂ is ejected at a high flow rate from the first ejector 221. The CO₂ loses momentum after colliding with the lower surface of the plate 215, and is then introduced into the upper space 211A inside the processing container 211 through the through-holes 218 and the elongated hole 219, or through the gap between the peripheral edge of the plate 215 and the inner wall surface of the processing container 211. As the CO₂ is introduced, an internal pressure of the processing container 211 is gradually increased.

When the internal pressure of the processing container 211 exceeds the critical pressure (approximately 8 MPa) of CO₂, the CO₂ present inside the processing container 211 (CO₂ not mixed with IPA) reaches a supercritical state. When the CO₂ inside the processing container 211 reaches the supercritical state, IPA on the substrate W begins to dissolve into the supercritical CO2. The first ejector 221 continues to eject CO₂, and the internal pressure of the processing container 211 continues to increase.

### Distribution Step

When the internal pressure of the processing container 211 reaches a level for guaranteeing that a mixed fluid (CO₂+IPA) on the substrate W remains in a supercritical state (supercritical state guaranteeing pressure of approximately 16 MPa) regardless of an IPA concentration in the mixed fluid and a temperature of the mixed fluid, the ejection of CO₂ from the first ejector 221 is stopped, ejection of CO₂ from the second ejector 22 is initiated, and discharge of CO₂ from the fluid discharger 224 is initiated. By controlling a discharge flow rate from the fluid discharger 224, the CO₂ is distributed into the processing container 211 while maintaining the internal pressure of the processing container 211 at the supercritical state guaranteeing pressure. In the distribution step, the supercritical CO₂ supplied from the second ejector 22 into the processing container 211 flows through a region above the substrate and is then discharged from the fluid discharger 24 (see arrows F in FIG. 3). At this time, a laminar flow of supercritical CO₂, flowing approximately parallel to the front surface of the substrate W, is created inside the processing container 211. The IPA in the mixed fluid (IPA+CO₂) on the front surface of the substrate W, which is exposed to the laminar flow of supercritical CO₂, is gradually replaced with the supercritical CO₂. Finally, almost all of the IPA on the front surface of the substrate W is replaced with the supercritical CO₂.

### Discharge Step

Once the replacement of the IPA with the supercritical CO₂ is completed, the supply of CO₂ to the processing container 211 is stopped, and the interior of the processing container 211 is connected to the atmospheric atmosphere through the fluid discharger 224. This allows the internal pressure of the processing container 211 to decrease to atmospheric pressure. Thus, the supercritical CO₂ present inside patterns on the substrate W transitions to a gas state and escapes from the patterns, with the gaseous CO₂ being discharged from the processing container 211. In this way, the drying of the substrate W (substrate drying step) is terminated.

### Substrate Unloading Step

The tray 212 where the dried substrate W is placed moves to the open position, and the substrate is unloaded from the supercritical drying unit 200 by using the aforementioned lift pins (not illustrated) and the transfer device 16 in a reverse sequence of the substrate loading step.

### Liquid Processing

Next, a series of steps executed in the liquid processing unit 100 is described. The following description assumes that the liquid processing unit 100 includes the following configuration:
The first processing fluid supplier 140 includes two nozzle arms 142, with one nozzle arm 142 referred to as “arm R” and the other nozzle arm 142 referred to as “arm L”;
A tip of the arm R carries the front surface nozzle 141 (also referred to as “front surface nozzle F1”) that selectively ejects hydrofluoric acid (HF) and deionized water (DIW) and the front surface nozzle 141 (also referred to as “front surface nozzle F2”) that ejects isopropyl alcohol (IPA);
A tip of the arm L carries the front surface nozzle 141 (also referred to as “front surface nozzle F3”) that ejects DIW and the front surface nozzle 141 (also referred to as “front surface nozzle F4”) that ejects a water-repellent liquid (such as organic silane); and
The second processing fluid supplier 150 includes the rear surface nozzle 151 (also referred to as “rear surface nozzle B1”) that ejects DIW and the rear surface nozzle 151 (also referred to as “rear surface nozzle B2”) that ejects IPA. In addition, both the rear surface nozzles B1 and B2 are provided to eject a liquid such that the liquid is applied to a position slightly away from a center of the rear surface of the substrate (the rotation center of the substrate). Also, one of the rear surface nozzles B1 and B2 may eject a liquid such that the liquid is applied to the rotation center of the substrate W, while the other may eject a liquid such that the liquid is applied to a position slightly away from the rotation center of the substrate W. In either case, the rear surface nozzles B1 and B2 eject the liquids such that the liquids are applied to the “central portion” of the substrate as defined later.

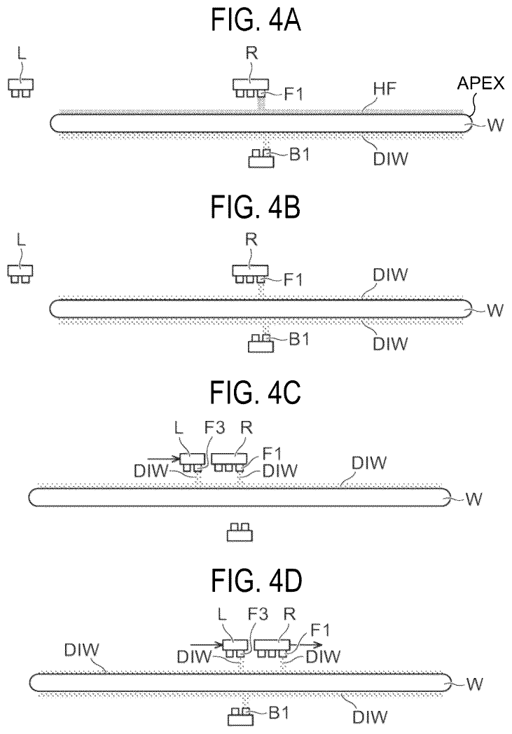

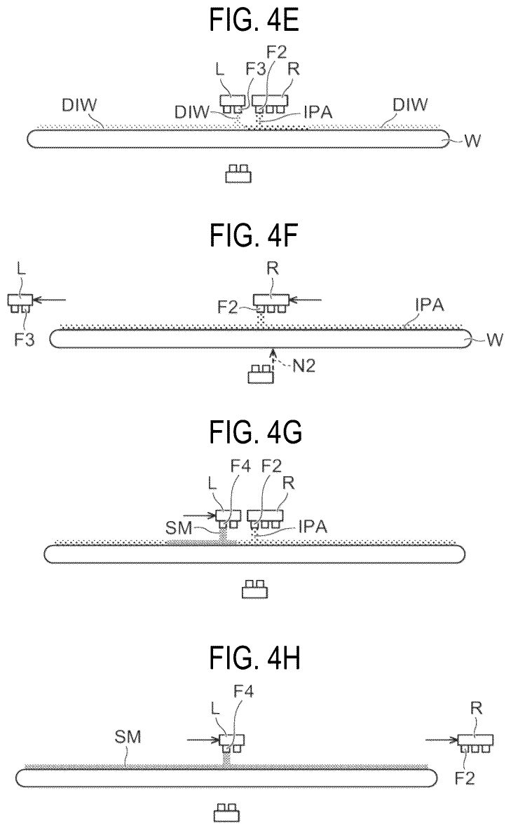

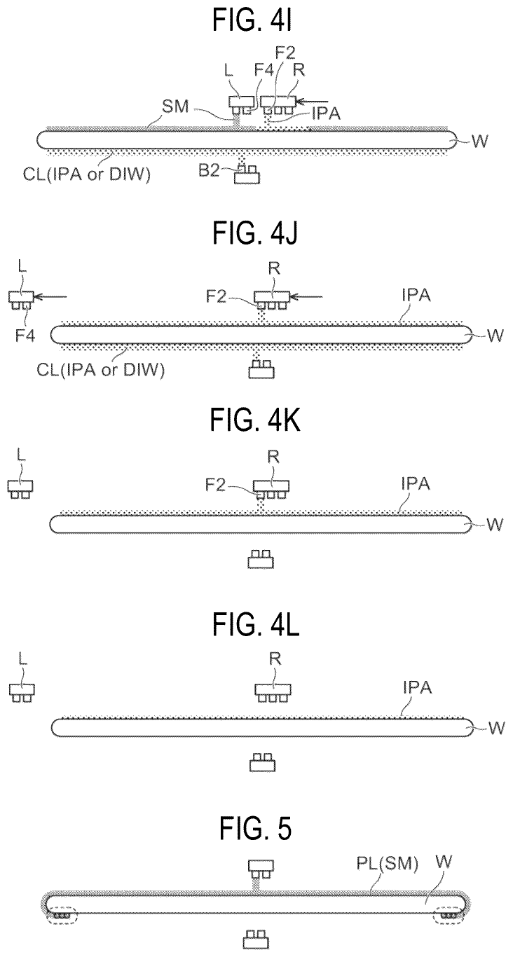

Hereinafter, each step is described. In addition, in operation diagrams for illustrating each step (FIGS. 4A to 4L), reference symbols are as follows: “R” and “L” for the nozzle arms 142; “F1,” “F2,” “F3,” and “F4” for the front surface nozzles 141; and “B1” and “B2” for the rear surface nozzles 151, for simplicity of the drawings. In FIGS. 4A to 4L, the front surface nozzle 141 located outside the substrate W is understood to be at the home position (standby position).

### Chemical Cleaning Step

The substrate W, which is loaded into the liquid processing unit 100 by the transfer device 16, is held in a horizontal posture by the substrate holder 131 of the substrate holding rotator 130. The substrate W is then rotated around the vertical axis by the substrate holding rotator 130. The rotation of the substrate W continues until a series of steps is terminated, with changes in the number of rotations as necessary.

In this state, as illustrated in FIG. 4A, the front surface nozzle F1 of the arm R is positioned directly above the central portion of the substrate W and supplies a chemical liquid, herein HF, so that the chemical liquid is applied to the central portion of the substrate W. Herein, the central portion of the substrate W in relation to a liquid application position is not limited to the center (rotation center) of the substrate, but also includes a position that is slightly away from the center of the substrate W on the front surface of the substrate W and where the liquid (herein, HF) spreads to the center of the substrate due to momentum thereof after being applied. The HF spreads to cover the entire front surface of the substrate W due to centrifugal force, thus flowing toward a peripheral edge of the substrate W. Thus, a silicon oxide film on the front surface of the substrate W is removed by the HF.

It is desirable to eject DIW from the rear surface nozzle B1 while the front surface nozzle F1 supplies the HF to the central portion of the substrate W. The DIW, applied to a central portion of the rear surface of the substrate, spreads to cover the entire rear surface of the substrate W due to centrifugal force, thus flowing toward the peripheral edge of the substrate W. In other words, the entire rear surface of the substrate W is covered with a liquid film of DIW. Therefore, it is possible to prevent the HF on the front surface of the substrate W from flowing around to the rear surface through the peripheral edge APEX of the substrate W, and it is possible to prevent the rear surface of the substrate W from being contaminated by, for example, contaminants derived from reaction products.

In addition, before this chemical cleaning step, a pre-wet processing may be performed, which involves supplying DIW from the front surface nozzle F1 of the arm R to the central portion of the front surface of the rotating substrate W to cover the entire front surface of the substrate with a DIW liquid film.

### Rinsing Step

Next, as illustrated in FIG. 4B, the processing liquid ejected from the front surface nozzle F1 is switched from HF to DIW while maintaining the position of the front surface nozzle F1. DIW supplied to the central portion of the substrate W spreads to cover the entire front surface of the substrate W by centrifugal force, thus flowing toward the peripheral edge of the substrate W. Thus, HF remaining on the front surface of the substrate W and reaction products generated during the chemical cleaning step are washed away from the front surface of the substrate W.

It is desirable to continue the ejection of DIW from the rear surface nozzle B1 until rinsing has progressed to sufficiently remove the HF remaining on the front surface of the substrate W and the reaction products generated during the chemical cleaning step.

Next, as illustrated in FIG. 4C, while continuing the ejection of DIW from the front surface nozzle F1, the front surface nozzle F3 of the arm L is positioned above the substrate W to initiate ejection of DIW from the front surface nozzle F3. Then, the front surface nozzle F3 is moved closer to the front surface nozzle F1 while continuing the ejection of DIW from the front surface nozzle F3. At this time, as the arms L and R come closer to each other, the arm R begins to be retracted to avoid collision with the arm L. In other words, slightly before the front surface nozzle F3 carried on the arm L reaches directly above the central portion of the substrate W, the front surface nozzle F1 carried on the arm R is retracted to a position slightly away from directly above the central portion of the substrate W. As illustrated in FIG. 4D, when the front surface nozzle F3, which is discharging DIW, reaches directly above the central portion of the substrate W, the ejection of DIW from the front surface nozzle F1 is stopped. The position of the front surface nozzle F1 and the arm R carrying it (also referred to as “temporary retracted position”) is maintained as it is.

### IPA Replacement Step (DIW→IPA)

Next, as illustrated in FIG. 4E, while continuing the ejection of DIW from the front surface nozzle F3 located directly above the central portion of the substrate W, ejection of IPA from the front surface nozzle F2 carried on the arm R at the temporary retracted position is initiated. Then, the front surface nozzle F2 is moved closer to the front surface nozzle F3 while continuing the ejection of DIW from the front surface nozzle F3. At this time, as the arms L and R come closer to each other, the arm L begins to be retracted to avoid collision with the arm R. In other words, slightly before the front surface nozzle F2 carried on the arm R reaches directly above the central portion of the substrate W, the front surface nozzle F1 carried on the arm L is moved from directly above the central portion of the substrate W toward the peripheral edge of the substrate W. As illustrated in FIG. 4F, when the front surface nozzle F2, which is discharging IPA, reaches a position directly above the central portion of the substrate W, the front surface nozzle F2 is stopped at that position, and the ejection of DIW from the front surface nozzle F3 is stopped. After that, the front surface nozzle F3 and the arm L carrying it are continuously moved to the home position, where they remain on standby.

By continuing the ejection of IPA from the front surface nozzle F2 located directly above the central portion of the substrate W for a predetermined time, DIW on the front surface of the substrate W (including interior of recesses of patterns formed on the front surface) is replaced with IPA. Since a water-repellent agent used in the next step, water-repellent processing step, has low affinity with DIW, it is difficult to directly replace DIW with the water-repellent agent. Therefore, DIW is first replaced with IPA, which has high affinity with DIW, and then, IPA is replaced with a water-repellent agent, which has high affinity with IPA.

In addition, in the next step, the water-repellent processing step, a water-repellent agent SM supplied to the front surface of the substrate W may flow around the peripheral edge APEX of the substrate W to the peripheral edge of the rear surface (see FIG. 5). This type of flow may occur to varying degrees with any liquid PL. At this time, if DIW supplied to the rear surface of the substrate W during the rinsing step has not dried and remains, for example, stains (deposits) may be formed as a result of reaction between the water-repellent agent and moisture in the region surrounded by the dashed line in FIG. 5, potentially leading to particle formation during subsequent supercritical drying. To prevent this phenomenon, it is desirable to supply the aforementioned drying gas (herein, nitrogen gas) to the rear surface of the substrate during the IPA replacement step (DIW→IPA). By supplying the drying gas to remove the moisture remaining on the rear surface of the substrate W, it is possible to prevent the formation of stains (deposits) described above. Further, in the IPA replacement step, IPA supplied to the front surface of the substrate W may also flow around to the peripheral edge APEX of the substrate W to the peripheral edge of the rear surface. The IPA adhering to the peripheral edge of the rear surface promotes a flow of the water-repellent agent, supplied to the front surface of the substrate W, around to the rear surface during the water-repellent processing step. In other words, when the water-repellent agent comes into contact with the IPA adhered to the peripheral edge of the rear surface, it is drawn to the IPA. This is undesirable from the perspective of preventing substances derived from the water-repellent agent from adhering to the rear surface. From this perspective as well, it is desirable to supply the aforementioned drying gas to the rear surface of the substrate during the IPA replacement step (DIW→IPA), and it is desirable to continuously eject the drying gas until just before the next step, switching step (IPA→water-repellent agent), is initiated.

### Switching Step (IPA→Water-Repellent Agent)

Next, while continuing the ejection of IPA from the front surface nozzle F2, the arm L is moved to bring the front surface nozzle F4 closer to the front surface nozzle F2. At this time, as the arms L and R come closer to each other, the arm R begins to be retracted to avoid collision with the arm L. In other words, the front surface nozzle F2 begins to move away from a position directly above the central portion of the substrate W. Further, almost simultaneously, ejection of a hydrophobic agent (denoted as reference symbol “SM” in the drawing) from the front surface nozzle F4 is initiated (see FIG. 4G).

When the front surface nozzle F4, which is discharging the hydrophobic agent, reaches a position directly above the central portion of the substrate W, the front surface nozzle F4 is stopped at that position. Almost simultaneously, the ejection of IPA from the front surface nozzle F2 is stopped, and the front surface nozzle F2 and the arm R carrying it are moved to the home position, where they remain on standby (see FIG. 4H).

In addition, in this switching step (IPA→water-repellent agent), as long as the front surface of the substrate W remains covered with a liquid film, there is no strict requirement for the timing for initiating the ejection of the water-repellent agent from the front surface nozzle F4 and the timing for stopping the ejection of IPA from the front surface nozzle F2. The timing for initiating the ejection of the water-repellent agent may be advanced, and the timing for stopping the ejection of IPA may be delayed. However, in general, since IPA and the water-repellent agent are relatively expensive chemical, the above timings are determined to reduce unnecessary consumption.

### Water-Repellent Processing Step

As illustrated in FIG. 4H, starting from the time point when the front surface nozzle F4, which is discharging the water-repellent agent, is positioned directly above the central portion of the substrate W, the ejection of the water-repellent agent from the front surface nozzle F4 is continued for a predetermined time. This allows IPA on the front surface of the substrate W (including the interior of recesses of patterns formed on the front surface) to be replaced with the water-repellent agent. Thereafter, by continuing the ejection of the water-repellent agent from the front surface nozzle F4 for the predetermined time, the front surface of the substrate W (including the interior of recesses of patterns formed on the front surface) is treated with the water-repellent agent to achieve a desired level of hydrophobicity.

For example, a silylating agent may be used as the water-repellent agent. Examples of the silylating agent include trimethylsilyldimethylamine (TMSDMA), hexamethyldisilazane (HMDS), trimethylsilyldiethylamine (TMSDEA), dimethyl (dimethylamino) silane (DMSDMA), and 1,1,3,3-tetramethyldisilane (TMDS).

### Switching Step (Water-Repellent Agent→IPA)

Next, as illustrated in FIG. 4I, while continuing the ejection of the water-repellent agent from the front surface nozzle F4 positioned directly above the central portion of the substrate W, the arm R is moved to bring the front surface nozzle F2 closer to the front surface nozzle F4. At this time, as the arms L and R come closer to each other, the arm L begins to be retracted to avoid collision with the arm R. In other words, the front surface nozzle F4 begins to move away from a position directly above the central portion of the substrate W. Further, almost simultaneously, the ejection of IPA from the front surface nozzle F2 is initiated. When the front surface nozzle F2, which is discharging IPA, reaches a position directly above the central portion of the substrate W, the front surface nozzle F2 is stopped at that position, and almost simultaneously, the ejection of the water-repellent agent from the front surface nozzle F4 is stopped. The front surface nozzle F4, which has stopped the ejection of the water-repellent agent, and the arm L carrying it are moved to the home position, where they remain on standby.

In addition, in this switching step (water-repellent agent→IPA) as well, as long as the front surface of the substrate W remains covered with a liquid film, there is no strict requirement for the timing for initiating the ejection of IPA from the front surface nozzle F2 and the timing for stopping the ejection of the water-repellent agent from the front surface nozzle F4. The timing for initiating the ejection of IPA may be advanced, and the timing for stopping the ejection of the water-repellent agent may be delayed.

### IPA Liquid Film Formation Step (IPA Replacement Step)

Starting from the time point when the front surface nozzle F2, which is discharging IPA, reaches a position directly above the central portion of the substrate W, the ejection of IPA from the front surface nozzle F2 is continued for a predetermined time. This allows the entire front surface of the substrate W to be covered with a liquid film of IPA, and simultaneously, the water-repellent agent on the front surface of the substrate W (including the interior of recesses of patterns formed on the front surface) to be replaced with IPA. In addition, at least while the IPA liquid film formation step (liquid film formation step) is performed, a rear surface cleaning step is actually performed on the rear surface of the substrate W, and this is described later.

### IPA Liquid Film Thickness Adjustment Step

Next, while continuing the ejection of IPA from the front surface nozzle F2, which is positioned directly above the central portion of the substrate W, a rotational speed of the substrate W is reduced, for example, from 1,000 rpm to a lower speed, for example, approximately 300 to 700 rpm (see FIG. 4K). Next, the rotational speed of the substrate is reduced to an extremely low final rotational speed, for example, 30 rpm, and the ejection of IPA from the front surface nozzle F2 is stopped (see FIG. 4L). By appropriately adjusting the final rotational speed, a film thickness of the IPA paddle (liquid film) remaining on the front surface of the substrate W may be adjusted. Finally, the rotation of the substrate W is stopped. In this way, the series of steps executed in the liquid processing unit 100 is completed. Thus, the patterns on the front surface of the substrate W are protected by the protective liquid IPA.

The substrate W with the IPA paddle formed thereon is unloaded from the liquid processing unit 100 by the transfer device 16 and is then loaded into the supercritical drying unit 200, where supercritical drying described above is performed on the substrate W in the supercritical drying unit 200.

### Rear surface Cleaning Step (Cleaning Step)

A rear surface cleaning step is performed at least during the execution of the IPA liquid film formation step. If the water-repellent agent supplied to the front surface of the substrate W flows around to the rear surface of the substrate W and is dried, for example, in the region illustrated by the dashed line in FIG. 5 (including entering a semi-dry state) in the water-repellent processing step, it may dissolve into a supercritical fluid (CO₂ or a mixture of CO₂ and IPA) during supercritical drying, potentially causing particle formation. In other words, during the pressure increasing step of supercritical drying described above, CO₂ ejected from the first ejector 221 into the lower space 211B of the processing container 211 passes through the through-holes 218, and then flows along the rear surface of the substrate W, entering the upper space 211A through near the peripheral edge of the rear surface of the substrate W. If a substance derived from the water-repellent agent adheres to the peripheral edge of the rear surface of the substrate W, the substance dissolves into CO₂, leading to particle formation. Further, in the distribution step of supercritical drying, some of the CO₂ flowing near the front surface of the substrate W flows from a gap between the peripheral edge of the substrate W and the plate 215 of the tray 212 and is then introduced into the space between the upper surface of the plate 215 and the rear surface of the substrate W. If a substance derived from the water-repellent agent adhered to the peripheral edge of the rear surface of the substrate W comes into contact with this CO₂ flow, the substance may dissolve into CO₂, potentially causing particle formation. To prevent particles from being formed through the above mechanism, the rear surface cleaning step is performed to remove the water-repellent agent that has flowed around to the rear surface of the substrate W. The rear surface cleaning step is described below.

The rear surface cleaning step may be performed by supplying a cleaning liquid, such as IPA, to the central portion of the rear surface of the rotating substrate W. The cleaning liquid is denoted by reference symbol CL in FIGS. 41 and 4J. The cleaning liquid supplied to the central portion of the rear surface of the substrate W flows toward the peripheral edge of the rear surface due to centrifugal force, so that the entire rear surface is covered with the cleaning liquid. By maintaining this state for a predetermined time, the rear surface of the substrate W is cleaned, and particularly, the water-repellent agent (or deposits derived from the water-repellent agent) adhered to the peripheral edge of the rear surface is removed. In addition, it is desirable for a temperature of the cleaning liquid to be in a moderate temperature range of 20 degrees C. to 75 degrees C. This may enhance removal efficiency of the water-repellent agent (herein, silylating agent).

In the rear surface cleaning step, it is desirable for a flow rate of the cleaning liquid supplied to the rear surface of the substrate W to be smaller than a flow rate of IPA (protective liquid) supplied to the front surface of the substrate W in the same case. This may prevent the cleaning liquid from flowing around from the rear surface to the front surface. Since the cleaning liquid may contain contaminants derived from deposits on the rear surface, preventing the cleaning liquid supplied to the rear surface from flowing around to the front surface is desirable for avoiding contamination of the front surface of the substrate W.

An end time point of the rear surface cleaning step is defined as a time point when the water-repellent agent that has flowed around to the rear surface is completely or nearly completely removed (Termination Condition 1) and when the possibility of the water-repellent agent flowing from the front surface of the substrate W to the rear surface is eliminated (Termination Condition 2). Termination Condition 2 is equivalent to a condition where the water-repellent agent on the front surface of the substrate W has been completely or nearly completely replaced with IPA. In addition, the aforementioned “nearly completely” means that even if an extremely small amount of the water-repellent agent remains, the impact thereof on particle formation during supercritical drying is negligible.

A time required from a start time point of the IPA liquid film formation step (an end time point of the switching step (water-repellent agent→IPA)), i.e., a time point when the front surface nozzle F2, which is discharging IPA, is positioned directly above the central portion of the substrate W (hereinafter referred to as “time point T1” for convenience), until the water-repellent agent on the front surface of the substrate W is substantially completely replaced with IPA (hereinafter referred to as “replacement time”) is, for example, 20 seconds (this varies depending on processing conditions). In this case, Termination Condition 2 is satisfied at the time point 20 seconds after time point T1.

A time required for the complete or nearly complete removal of the water-repellent agent that has flowed around to the rear surface (hereinafter also referred to as “rear surface cleaning time”) is at most the same as the “replacement time.” Therefore, the rear surface cleaning step and the switching step (water-repellent agent→IPA) may be initiated at the same timing and terminated at the same timing. In other words, if the rear surface cleaning step is initiated at time point T1, it may also be stopped (terminated) at an end time point of the IPA liquid film formation step (IPA replacement step) (time point 20 seconds after time point T1).

The rear surface cleaning step may also be initiated before time point T1, for example, simultaneously with an initiation of the switching step (water-repellent agent→IPA), or during the switching step (water-repellent agent→IPA). By initiating the rear surface cleaning step earlier, the removal of the water-repellent agent adhered to the rear surface of the substrate W (particularly the peripheral edge thereof) may be expedited, allowing for an earlier termination of the rear surface cleaning step. If the rear surface cleaning step is terminated earlier, subsequent rear surface drying may also be terminated earlier. In cases where the drying of the rear surface is required, even after the completion of the IPA liquid film formation step (IPA replacement step), the transition to the IPA liquid film thickness adjustment step, which is performed at a low rotational speed, needs to wait until the rear surface is dried. Therefore, in some cases (for example, when the cleaning liquid is DIW), the IPA liquid film formation step (IPA replacement step) needs to be unnecessarily extended, which may cause issues such as an unnecessarily increased amount of IPA supplied to the front surface of the substrate W and an increased processing time (leading to a decrease in throughput). These issues may be resolved by initiating the rear surface cleaning step earlier.

In addition, it might be assumed that if the rear surface cleaning step is terminated before the IPA liquid film formation step (IPA replacement step) is completed, the water-repellent agent remaining on the front surface of the substrate may flow around to the rear surface, contaminating the rear surface; however, this does not happen in actual processing. In actual processing, to ensure that the water-repellent agent does not remain in the IPA paddle, the processing time is slightly extended. In other words, the processing time is set as a time required for the complete replacement of the water-repellent agent with IPA (replacement time) plus a safety margin time. In other words, by the end of the replacement time, IPA on the front surface of the substrate W contains no water-repellent agent at all, or at most, an extremely small amount. Even if such IPA flows around to the rear surface, it would not cause a substantial problem on the state of the rear surface. In other words, it is acceptable to terminate the rear surface cleaning step at a beginning of a safety margin time at the latest. Accordingly, initiating the rear surface cleaning step at least as early as the safety margin time does not present a problem.

In addition, FIGS. 4I and 4J illustrate an example where IPA as the cleaning liquid is discharged from the rear surface nozzle B2 during the switching step (water-repellent agent-IPA).

When the discharge of IPA from the rear surface nozzle B2 is stopped while the substrate W is rotating, the cleaning liquid on the rear surface of the substrate W is spun off, thereby drying the rear surface. If a sufficiently dried rear surface is desired, the substrate W needs to be rotated at a relatively high speed (e.g., 1,000 rpm) for a predetermined time (e.g., approximately 10 seconds in the case of IPA as the cleaning liquid) after the completion of the rear surface cleaning step (i.e., after stopping the ejection of the cleaning liquid from the rear surface nozzle B2).

Generally, no problem arises even if the substrate undergoes unloading from the liquid processing unit, loading into the supercritical processing unit, and a supercritical processing while IPA remains adhered to the rear surface of the substrate W. In fact, this may sometimes help in retaining the IPA paddle inside the processing container of the supercritical processing unit. Therefore, after stopping the ejection of IPA from the rear surface nozzle B2, it is acceptable to immediately reduce the rotational speed of the substrate W and adjust the IPA film thickness without taking an additional time to dry the rear surface.

The cleaning liquid CL used in the rear surface cleaning step is not limited to IPA, but other cleaning liquids such as DIW may also be used. In this case, the cleaning liquid may be ejected from the rear surface nozzle L1. DIW also has a removal performance of deposits derived from the water-repellent agent that is roughly equivalent to IPA. However, if supercritical drying is performed with DIW adhered to the rear surface of the substrate W, it may result in a problem (such as pattern collapse or particle formation) during the supercritical drying step. Therefore, it is necessary to sufficiently dry the rear surface of the substrate W before unloading the substrate W from the liquid processing unit. Similarly to when IPA is used as the cleaning liquid, drying is performed by continuously rotating the substrate W at a relatively high speed (e.g., 1,000 rpm) for a predetermined time after the termination of the rear surface cleaning step (i.e., after stopping the ejection of DIW from the rear surface nozzle B1). To dry DIW on the rear surface, a longer time (e.g., approximately 40 seconds at 1,000 rpm) is required compared to drying IPA. In addition, to promote the drying of DIW on the rear surface, a drying gas (such as nitrogen gas) may be sprayed onto the rear surface of the substrate W.

DIW is cheaper than IPA, and therefore, has an advantage of reducing an apparatus running cost. On the other hand, IPA is more volatile than DIW, and therefore, has an advantage of a shorter rear surface drying time. The choice of whether to use DIW or IPA as the cleaning liquid of the rear surface needs to be made considering this trade-off relationship.

In addition, since some water-repellent agents may cause a problem when coexisting with moisture (water), it is desirable to use IPA as the cleaning liquid when using such water-repellent agents. In addition, it is also possible to use a mixture of DIW and IPA as the cleaning liquid CL in the rear surface cleaning step.

### Experiment

A test was conducted to compare amounts of particles by performing a liquid processing and supercritical drying on a substrate using the liquid processing unit 100 and the supercritical drying unit 200 according to the following four methods.

### Processing Method 1 (Reference Example)

DIW pre-wet→chemical cleaning step (HF cleaning)→rinsing step (DIW rinsing)→IPA replacement step (DIW→IPA)→switching step (IPA→water-repellent agent)→water-repellent processing step→switching step (water-repellent agent→IPA)→IPA liquid film formation step (IPA replacement step)→spin drying step (supercritical drying not used for final drying).

### Processing Method 2 (Comparative Example 1)

DIW pre-wet→chemical cleaning step (HF cleaning)→rinsing step (DIW rinsing)→IPA replacement step (DIW→IPA) (no drying gas supplied to the rear surface at this stage)→switching step (IPA→water-repellent agent)→water-repellent processing step→switching step (water-repellent agent→IPA)→IPA liquid film formation step (IPA replacement step) (rear surface cleaning step not performed at this stage)→IPA liquid film thickness adjustment step→supercritical drying of substrate with IPA paddle formed.

### Processing Method 3 (Comparative Example 2)

DIW pre-wet→chemical cleaning step (HF cleaning)→rinsing step (DIW rinsing)→IPA replacement step (DIW→IPA) (drying gas supplied to the rear surface at this stage)→switching step (IPA→water-repellent agent)→water-repellent processing step→switching step (water-repellent agent→IPA)→IPA liquid film formation step (IPA replacement step) (rear surface cleaning step not performed at this stage)→IPA liquid film thickness adjustment step→supercritical drying of substrate with IPA paddle formed.

### Processing Method 4 (Embodiment)

DIW pre-wet→chemical cleaning step (HF cleaning)→rinsing step (DIW rinsing)→IPA replacement step (DIW→IPA) (drying gas supplied to the rear surface at this stage)→switching step (IPA→water-repellent agent)→water-repellent processing step→switching step (water-repellent agent→IPA)→IPA liquid film formation step (IPA replacement step) (rear surface cleaning step performed at this stage)→IPA liquid film thickness adjustment step→supercritical drying of substrate with IPA paddle formed.

An increase in the number of particles larger than 19 nm before and after processing for each substrate W was investigated. The results showed that the increase was 205 particles for Processing Method 1, the increase was 4,301 particles for Processing Method 2, the increase was 2,168 particles for Processing Method 3, and the increase was 286 particles for Processing Method 4. In addition, for Processing Methods 2 and 3, particles were significantly distributed toward one side, which is believed to be due to factors such as an uneven flow of CO₂ through the gap between the peripheral edge of the substrate W and the plate 215 of the tray 212 in the supercritical drying unit (see the description at the beginning of the rear surface cleaning step).

From the above test results, it may be appreciated that when the water-repellent processing followed by the supercritical drying is performed, a significant increase in particles occurs without the rear surface cleaning (Processing Methods 2 and 3) (the presumed mechanism has been described above). However, it was confirmed that when the rear surface cleaning is performed (Processing Method 4), an increase in particles is reduced to approximately the same level as Processing Method 1. In addition, needless to say, Processing Method 4, which involves the supercritical drying, is overwhelmingly advantageous over Processing Method 1, which involves spin drying, in terms of pattern collapse prevention. In addition, by comparing Processing Methods 2 and 3, it may be appreciated that an increase in particles may be prevented by supplying a drying gas to the rear surface during the IPA replacement step (DIW→IPA).

As described above, according to the above embodiments, by performing the rear surface cleaning step while performing the IPA liquid film formation step (IPA replacement step) on the front surface of the substrate W, it is possible to significantly reduce the amount of particles after the supercritical drying.

The embodiments disclosed herein should be considered illustrative in all respects and not restrictive. The above embodiments may be omitted, replaced or modified in various embodiments without departing from the scope of the appended claims and their gist.

The substrate is not limited to a semiconductor wafer but may be other types of substrates used in manufacturing semiconductor devices, such as a glass substrate and a ceramic substrate.

The protective liquid is not limited to IPA, but an organic solvent with high affinity with the water-repellent agent, high affinity with the supercritical fluid used in the supercritical drying, and low surface tension, such as hydrofluoroether (HFE) or a mixture of IPA and HFE, may be used instead of IPA.

In the above-described embodiments, the steps before the first IPA replacement step (DIW→IPA) may be arbitrarily modified. For example, two or more types of chemical processing may be performed before the first IPA replacement step.

The purpose of the rear surface cleaning step may be other than the removal of the water-repellent agent or the substances derived from the water-repellent agent. For example, if residues and reaction products of a chemical liquid adhere to the peripheral edge of the rear surface of the substrate, these may also be potential sources of particles in the supercritical drying, and therefore, the rear surface cleaning step may also be performed for the purpose of removing such substances. In other words, the rear surface cleaning step may be performed to remove deposits on the rear surface of the substrate that may result from the processing with a processing liquid (this is not limited to the water-repellent agent, and may be a chemical liquid such as HF, for example) used prior to the IPA liquid film formation step.

1. A substrate processing method comprising:
forming a liquid film of a protective liquid, which covers a front surface of a substrate, by supplying the protective liquid, which protects a front surface pattern of the substrate, to the front surface of the substrate on which a liquid processing using a processing liquid has been performed;
loading the substrate, after the forming the liquid film, into a processing container in a state where the liquid film of the protective liquid is formed;
supplying a pressurized processing fluid, after the loading the substrate, into the processing container, replacing the processing liquid on the substrate with the pressurized processing fluid supplied into the processing container while maintaining an internal pressure of the processing container at a level where the processing fluid remains in a supercritical state, discharging the processing fluid from the processing container, and drying the substrate; and
cleaning a rear surface of the substrate by supplying a cleaning liquid, which cleans the rear surface of the substrate, to the rear surface of the substrate,
wherein the cleaning the rear surface is performed at least while the forming the liquid film is performed.

2. The substrate processing method of claim 1, wherein the processing liquid is a water-repellent agent that makes the front surface of the substrate water-repellent.

3. The substrate processing method of claim 2, wherein the cleaning liquid is one of deionized water, IPA, or a mixed liquid of deionized water and IPA.

4. The substrate processing method of claim 3, wherein the cleaning liquid supplied to the rear surface of the substrate has a temperature of 20 degrees C. to 75 degrees C.

5. The substrate processing method of claim 2, wherein the cleaning liquid is IPA and the protective liquid is also IPA.

6. The substrate processing method of claim 1, wherein when the forming the liquid film is being performed on the front surface of the substrate and the cleaning the rear surface is being performed on the rear surface of the substrate, a supply flow rate of the protective liquid to the front surface is greater than or equal to a supply flow rate of the cleaning liquid to the rear surface.

7. The substrate processing method of claim 1, wherein the cleaning the rear surface is terminated after a predetermined time is passed from initiation of the forming the liquid film.

8. The substrate processing method of claim 2, wherein the supply of the cleaning liquid in the cleaning the rear surface is initiated when the water-repellent agent and the protective liquid are simultaneously supplied to the front surface of the substrate, during transition from the liquid processing using the water-repellent agent as the processing liquid to the forming the liquid film.

9. The substrate processing method of claim 2, wherein the supply of the cleaning liquid in the cleaning the rear surface is initiated simultaneously at a time point when transition from the liquid processing using the water-repellent agent as the processing liquid to the forming the liquid film is terminated, which is when supply of the water-repellent agent is stopped.

10. The substrate processing method of claim 1, wherein the protective liquid is supplied to a center of the front surface of the rotating substrate, and the cleaning liquid is supplied to a position that is away from a center of the rear surface of the rotating substrate and to a position where the cleaning liquid that spreads after being applied to the rear surface reaches the center of the rear surface of the substrate.

11. A substrate processing apparatus comprising:
at least one liquid processing unit; and
at least one supercritical drying unit,
wherein the liquid processing unit includes:
a substrate holding rotator that holds a substrate in a horizontal posture and rotates the substrate around a vertical axis; and
a processing fluid supplier including at least one front surface nozzle capable of supplying at least a processing liquid and a protective liquid to a front surface of the substrate held and rotated by the substrate holding rotator, at least one rear surface nozzle capable of supplying at least a cleaning liquid to a rear surface of the substrate held and rotated by the substrate holding rotator, and a processing fluid supply mechanism that supplies a liquid necessary for a processing to the at least one front surface nozzle and the at least one rear surface nozzle, and
wherein the substrate processing apparatus further comprises a controller that controls operation of the liquid processing unit and the supercritical drying unit to execute the substrate processing method of claim 1.

12. A non-transitory computer-readable storage medium storing a computer program that, when executed by a computer constituting a controller of a substrate processing apparatus, causes the computer to control the substrate processing apparatus to execute the substrate processing method of claim 1.
